(19) United States
(12) Patent Application Publication
(10) Pub. No.: US 2025/0031490 A1
(43) Pub. Date: Jan. 23, 2025

(54) MICRO LED STRUCTURE AND MICRO DISPLAY PANEL

(71) Applicant: JADE BIRD DISPLAY (SHANGHAI) LIMITED, SHANGHAI (CN)

(72) Inventors: Yuankun ZHU, Shanghai (CN); Anle FANG, Shanghai (CN); Deshuai LIU, Shanghai (CN)

(21) Appl. No.: 18/788,011

(22) Filed: Jul. 29, 2024

Related U.S. Application Data
(63) Continuation of application No. PCT/CN2022/075290, filed on Jan. 31, 2022.

(51) Int. Cl. H01L 33/24; H01L 25/075; H01L 33/00; H01L 33/06; H01L 33/36; H01L 33/46; H01L 33/60; H01L 33/62

(52) U.S. Cl. CPC H01L 33/24; H01L 25/0753; H01L 33/0093; H01L 33/06; H01L 33/36; H01L 33/46; H01L 33/60; H01L 33/62

(57) ABSTRACT

A micro light emitting diode (LED) structure, includes a mesa structure. The mesa structure further includes a first semiconductor layer having a first conductive type, a light emitting layer formed on the first semiconductor layer, a second semiconductor layer formed on the light emitting layer, the second semiconductor layer having a second conductive type different from the first conductive type. The second semiconductor layer further includes a semiconductor region and an ion implantation region formed around the semiconductor region, the ion implantation region having a resistance higher than a resistance of the semiconductor region.

### CROSS-REFERENCE TO RELATED APPLICATIONS

This patent application is a continuation of Patent Cooperation Treaty Application No. PCT/CN2022/075290, filed Jan. 31, 2022, which is incorporated by reference herein in its entirety.

### TECHNOLOGY FIELD

The disclosure generally relates to a light emitting diode technology field and, more particularly, to a micro light emitting diode (LED) structure and a micro display panel comprising the micro LED structure.

### BACKGROUND

Inorganic micro light emitting diodes (also referred to as “micro LEDs” or “μ-LEDs”) are more and more important because of their use in various applications including, for example, self-emissive micro-displays, visible light communications, and opto-genetics. The μ-LEDs have greater output performance than conventional LEDs due to better strain relaxation, improved light extraction efficiency, uniform current spreading, etc. Compared with the conventional LEDs, the μ-LEDs feature in improved thermal effects, improved operation at higher current density, better response rate, greater operating temperature range, higher resolution, higher color gamut, higher contrast, lower power consumption, etc.

The μ-LEDs include III-V group epitaxial layers to form multiple mesas. In some μ-LED designs, space needs to be formed between adjacent μ-LEDs to avoid carriers in the epitaxial layers spreading from one mesa to an adjacent mesa. The space formed between the adjacent micro LEDs may reduce the active light emitting area and decrease the light extraction efficiency. Eliminating the space may increase the active light emitting area, but it would cause the carriers in the epitaxial layers to spread laterally across adjacent mesas and thus reduce the light emitting efficiency. Furthermore, without the space between the adjacent mesas, crosstalk will be produced between the adjacent μ-LEDs, which would cause the μ-LEDs to be less reliable or accurate.

Additionally, in some μ-LEDs structures, small LED pixels with high current density will more likely experience red-shift, lower maximum efficiency, and inhomogeneous emission, which are usually caused by degraded electrical injection during fabrication. Moreover, the peak external quantum efficiencies (EQEs) and the internal quantum efficiency (IQE) of the μ-LEDs can be greatly decreased with the decreasing chip size. The decreased EQE and IQE is caused by nonradiative recombination at the sidewalls of the quantum well that are not properly etched. The decreased IQE is caused by poor current injection and electron leakage current of μ-LEDs. Improving the EQE and IQE requires optimization of the quantum well sidewall area to reduce the current density.

### SUMMARY

In accordance with the present disclosure, there is provided a micro LED structure. The structure includes a mesa structure. The mesa structure further includes a first semiconductor layer having a first conductive type, a light emitting layer formed on the first semiconductor layer, a second semiconductor layer formed on the light emitting layer, the second semiconductor layer having a second conductive type different from the first conductive type, a sidewall protective layer formed on the sidewalls of the mesa structures, and a sidewall reflective layer formed on the surface of the sidewall protective layer. The second semiconductor layer further includes a semiconductor region and an ion implantation region formed around the semiconductor region, the ion implantation region having a resistance higher than a resistance of the semiconductor region.

Also in accordance with the present disclosure, there is provided a micro display panel. The micro display panel includes a micro LED array. The micro LED array includes a first micro LED structure and an integrated circuit (IC) back plane formed under the first micro LED structure. The first micro LED structure is electrically coupled to the IC back plane.

### BRIEF DESCRIPTION OF THE DRAWINGS

FIG. 1 is a schematic cross-sectional view of a micro LED structure, according to an exemplary embodiment of the present disclosure;

FIG. 2 is a flow chart of a method for manufacturing the micro LED structure as shown in FIG. 1, according to an exemplary embodiment of the present disclosure;

FIG. 3 is a cross-sectional diagram schematically illustrating a step for implementing the method of FIG. 2, according to an exemplary embodiment of the present disclosure;

FIG. 4 is a cross-sectional diagram schematically illustrating a step for implementing the method of FIG. 2, according to an exemplary embodiment of the present disclosure;

FIG. 5 is a cross-sectional diagram schematically illustrating a step for implementing the method of FIG. 2, according to an exemplary embodiment of the present disclosure;

FIG. 6 is a cross-sectional diagram schematically illustrating a step for implementing the method of FIG. 2, according to an exemplary embodiment of the present disclosure;

FIG. 7 is a cross-sectional diagram schematically illustrating a step for implementing the method of FIG. 2, according to an exemplary embodiment of the present disclosure;

FIG. 8 is a cross-sectional diagram schematically illustrating a step for implementing the method of FIG. 2, according to an exemplary embodiment of the present disclosure;

FIG. 9 is a cross-sectional diagram schematically illustrating a step for implementing the method of FIG. 2, according to an exemplary embodiment of the present disclosure;

FIG. 10 is a cross-sectional diagram schematically illustrating a step for implementing the method of FIG. 2, according to an exemplary embodiment of the present disclosure;

FIG. 11 is a cross-sectional diagram schematically illustrating a step for implementing the method of FIG. 2, according to an exemplary embodiment of the present disclosure; and

FIG. 12 is a cross-sectional diagram schematically illustrating a step for implementing the method of FIG. 2, according to an exemplary embodiment of the present disclosure;

FIG. 13 is a schematic cross-sectional view of at least a portion of an exemplary micro display panel, according to an exemplary embodiment of the present disclosure;

FIG. 14 is a cross-sectional diagram schematically illustrating a step for implementing the method of FIG. 13, according to an exemplary embodiment of the present disclosure;

FIG. 15 is a cross-sectional diagram schematically illustrating a step for implementing the method of FIG. 13, according to an exemplary embodiment of the present disclosure;

FIG. 16 is a cross-sectional diagram schematically illustrating a step for implementing the method of FIG. 13, according to an exemplary embodiment of the present disclosure;

FIG. 17 is a cross-sectional diagram schematically illustrating a step for implementing the method of FIG. 13, according to an exemplary embodiment of the present disclosure;

FIG. 18 is a cross-sectional diagram schematically illustrating a step for implementing the method of FIG. 13, according to an exemplary embodiment of the present disclosure;

FIG. 19 is a cross-sectional diagram schematically illustrating a step for implementing the method of FIG. 13, according to an exemplary embodiment of the present disclosure;

FIG. 20 is a cross-sectional diagram schematically illustrating a step for implementing the method of FIG. 13, according to an exemplary embodiment of the present disclosure;

FIG. 21 is a cross-sectional diagram schematically illustrating a step for implementing the method of FIG. 13, according to an exemplary embodiment of the present disclosure;

FIG. 22 is a cross-sectional diagram schematically illustrating a step for implementing the method of FIG. 13, according to an exemplary embodiment of the present disclosure;

FIG. 23 is a cross-sectional diagram schematically illustrating a step for implementing the method of FIG. 13, according to an exemplary embodiment of the present disclosure;

FIG. 24 is a cross-sectional diagram schematically illustrating a step for implementing the method of FIG. 13, according to an exemplary embodiment of the present disclosure; and

FIG. 25 is a cross-sectional diagram schematically illustrating a step for implementing the method of FIG. 13, according to an exemplary embodiment of the present disclosure;

FIG. 26 is a cross-sectional diagram schematically illustrating a step for implementing the method of FIG. 13, according to an exemplary embodiment of the present disclosure;

FIG. 27 is a cross-sectional diagram schematically illustrating a step for implementing the method of FIG. 13, according to an exemplary embodiment of the present disclosure;

FIG. 28 is a cross-sectional diagram schematically illustrating a step for implementing the method of FIG. 13, according to an exemplary embodiment of the present disclosure; and

FIG. 29 is a cross-sectional diagram schematically illustrating a step for implementing the method of FIG. 13, according to an exemplary embodiment of the present disclosure.

### DETAILED DESCRIPTION OF THE EMBODIMENTS

Hereinafter, embodiments consistent with the disclosure will be described with reference to the drawings. Wherever possible, the same reference numbers will be used throughout the drawings to refer to the same or like parts.

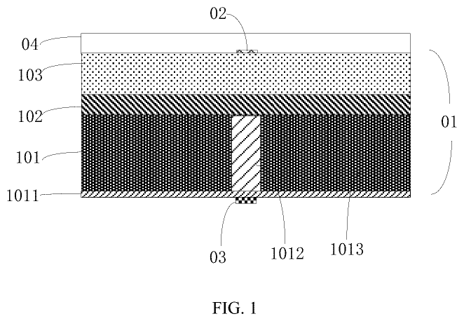

As discussed above, the state-of-art micro LEDs may experience problems like red-shift, low maximum efficiency, inhomogeneous emission, etc. To resolve these problems, a micro LED structure is provided in embodiments of the present invention. In some embodiments consistent with FIG. 1, a micro LED structure includes a mesa structure 01, a top contact 02, a bottom contact 03, and a top conductive layer 04. The mesa structure 01 further includes a first type semiconductor layer 101, a light emitting layer 102, and a second type semiconductor layer 103. The light emitting layer 102 is formed on the top of the first type semiconductor layer 101. The second type semiconductor layer 103 is located on the top of the light emitting layer 102. In some embodiments, the first type and the second type refer to different conductive types. For example, the first type is P type, while the second type is N type. In another example, the first type is N type, while the second type is P type.

In some embodiments, the material of the first type semiconductor layer 101 includes at least one of the p-GaAs, p-GaP, p-AlInP, p-GaN, p-InGaN, p-AlGaN, etc. The material of the second type semiconductor layer 103 includes at least one of the n-GaAs, n-AlInP, n-GaInP, n-AlGaAs, n-AlGaInP, n-InGaN, n-AlGaN, etc. The light emitting layer 102 is formed by a quantum well layer. The material of the quantum well layer includes at least one of the GaAs, InGaN, AlGaN, AlInP, GaInP, AlGaInP, etc. In some further embodiments, the thickness of the first type semiconductor layer 101 is greater than the thickness of the second type semiconductor layer 103, and the thickness of the light emitting layer 102 is less than the thickness of the first type semiconductor layer 101. In some embodiments, the thickness of the first type semiconductor layer 101 ranges from 700 nm to 2 μm and the thickness of the second type semiconductor layer 103 ranges from 100 nm to 200 nm. In some embodiments, the thickness of the quantum well layer is less than or equal to 30 nm. In some embodiments, the quantum well layer includes not more than three pairs of quantum wells.

In some embodiments, the first type semiconductor layer 101 includes one or more reflective mirrors 1011. In some embodiments, the reflective mirror 1011 is formed at the bottom surface of the first type semiconductor layer 101. In some embodiments, the reflective mirror 1011 is formed inside of the first type semiconductor layer 101. In some embodiments, the material of the reflective mirror 1011 is a mixture of dielectric material and metal material. In some further embodiments, the dielectric material includes SiO2 or SiNx, in which “x” is a positive integer. In some embodiments, the metal material includes Au or Ag. In some embodiments, multiple reflective mirrors 1011 are horizontally formed in the first type semiconductor layer 1011 one by one in different horizontal levels, dividing the first type semiconductor layer 101 into multiple layers.

In some embodiments, the top contact 02 is formed at the top surface of the second type semiconductor layer 103. The conductive type of the top contact 02 is the same as the conductive type of the second type semiconductor layer 103. For example, if the second type is N type, the top contact 02 is an N type contact; or if the second type is P type, the top contact 02 is a P type contact. In some embodiments, the top contact 02 is made by metal or metal alloy including at least one of AuGe, AuGeNi, etc. The top contact 02 is used for forming ohmic contact between the top conductive layer 04 and the second type semiconductor layer 103, optimizing the electrical property of the micro LEDs. In some embodiments, the diameter of the top contact 02 ranges from 20 nm to 50 nm and the thickness of the top contact 02 ranges from 10 nm to 20 nm.

In some embodiments, the first semiconductor layer 101 includes a first semiconductor region 1012 and an ion implantation region 1013. The first type semiconductor region 1012 is formed directly on the top surface of the bottom contact 03. The ion implantation region 1013 is formed around the first type semiconductor region 101. In some embodiments, the resistance of the ion implantation region 1013 is greater than the resistance of the first type semiconductor region 1012. In some embodiments, the ion implantation region 1013 is formed by implanting ions into the ion implantation region 1013.

In some embodiments, the center of the bottom contact 03 is aligned with the center of the first type semiconductor region 1012 along an axis perpendicular to the top surface of the first type semiconductor region 1012. In some embodiments, the diameter of the ion implantation region 1013 is greater than or equal to the diameter of the bottom contact 03. In some embodiments, the diameter of the first type semiconductor region 1012 is greater than or equal to the diameter of the bottom contact 03. In some embodiments, the diameter of the ion implantation region 1013 is greater than the diameter of the first type semiconductor region 1012. In some embodiments, the diameter of the first type semiconductor region 1012 is less than or equal to three times of the diameter of the bottom contact 03. In some embodiments, the diameter of the ion implantation region 1013 is greater than two times of the diameter of the diameter of the first type semiconductor region 1012. In some embodiments, the conductive type of the ion implantation region 1032 is the same as the conductive type of the second type semiconductor region 1031.

In some embodiments, the diameter of the ion implantation region 1013 ranges from 500 nm to 1250 nm and the diameter of the bottom contact 03 ranges from 20 nm to 500 nm. In some embodiments, the conductive type of the ion implantation region 1013 is the same as the first type semiconductor region 1012. In some further embodiments, the ion implantation region 1013 comprises at least one type of implanted ions. In some embodiments, the implanted ions are selected from one or more of the following ions: hydrogen, nitrogen, fluorine, oxygen, carbon, argon, phosphorus, boron, silicon, sulfur, arsenic, chlorine, and metal ions. The metal ions are selected from one or more of the following ions: zinc, copper, indium, aluminum, nickel, titanium, magnesium, chromium, gallium, tin, antimony, tellurium, tungsten, tantalum, germanium, molybdenum, and platinum. The thickness of the first type semiconductor region 1012 is greater than or equal to the thickness of the ion implantation region 1013. In some embodiments, the thickness of the second semiconductor layer 103 ranges from 100 nm to 200 nm, the thickness of the first type semiconductor region 1012 ranges from 600 nm to 900 nm, and the thickness of the ion implantation region 1013 ranges from 500 nm to 800 nm.

Still referring to FIG. 1, in some embodiments, the micro LED structure further includes a top conductor layer 04 covering the top surface of the second type semiconductor layer 103 and the top contact 02. The top conductive layer 04 is transparent and electrically conductive. In some embodiment, the top conductive layer 04 includes at least one of indium tin oxide (ITO) and fluorine-doped tin oxide (FTO).

In some embodiments, the bottom contact 03 is formed at the bottom surface of the first type semiconductor layer 101. The conductive type of the bottom contact 03 is the same as the conductive type of the first type semiconductor layer 101. For example, if the first type semiconductor layer 101 is P type, the bottom contact 03 is also P type. Similarly, if the first type semiconductor layer 101 is N type, the bottom contact 03 is also N type. In some embodiments, the light emits from the top surface of the mesa structure 01. To this end, the diameter of the bottom contact 03 is made greater than the diameter of the top contact 02, and the diameter of the top contact 02 is made as small as possible such that the top contact 02 is like a dot on the top surface of the second type semiconductor layer 103. In some embodiments, the diameter of the bottom contact 03 is made equal to or smaller than the diameter of the top contact 02. In some embodiments, the bottom contact 03 is configured to connect to a bottom electrode such as a contact pad in an IC back plane. In some embodiments, the diameter of the bottom contact 03 ranges from 20 nm to 1 μm. In some embodiments, the diameter of the bottom contact 03 ranges from 800 nm to 1 μm. In some embodiments, the center of the bottom contact 03 is aligned with the center of the top contact 02 along an axis perpendicular to the upper surface of the second type semiconductor region. In some embodiments, the center of the bottom contact 03, the center of the top contact 02, and the center of the second type semiconductor region are all aligned along an axis perpendicular to the upper surface of the second type semiconductor region. In some embodiments, the material of the bottom contact 03 includes transparent conductive material. In some further embodiments, the material of the bottom contact 03 includes ITO or FTO. In some embodiments, the bottom contact 03 is not transparent and the material of the bottom contact is conductive metal. In some embodiments, the material of the bottom contact includes at least one of the following elements: Au, Zn, Be, Cr, Ni, Ti, Ag, and Pt.

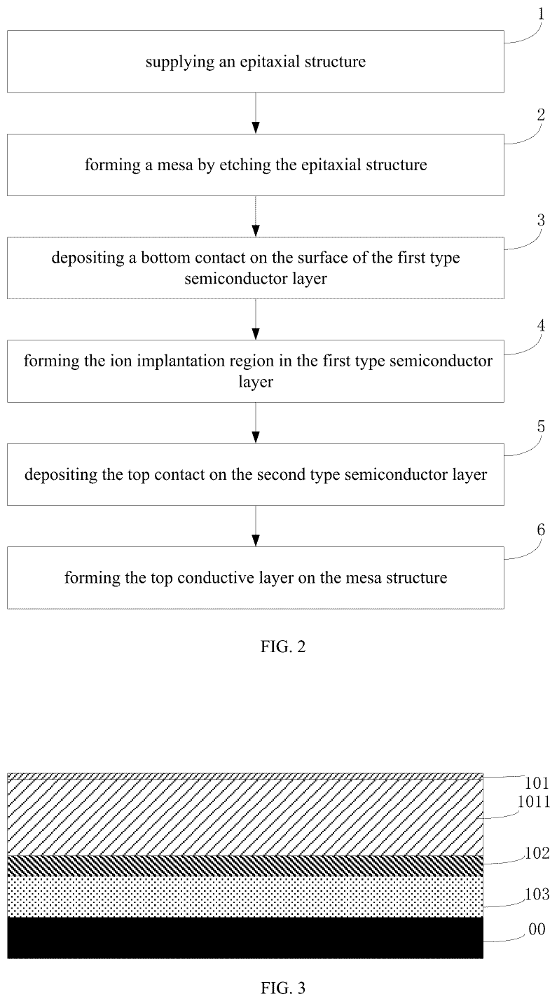

FIG. 2 is a flow chart of a method for manufacturing a micro LED structure, consistent with embodiments of the present disclosure. FIGS. 3 to 12 are cross-sectional diagrams schematically showing steps for implementing the method of FIG. 2. It is contemplated the disclosed manufacturing method is not limited to the particular micro LED structures shown in FIGS. 3 to 12. In some embodiments consistent with FIGS. 3 to 12, the method of manufacturing the aforementioned micro LED structure is described herewith.

In some embodiments consistent with FIG. 3, an epitaxial structure is provided (step 1 in FIG. 2). The epitaxial structure includes a first type semiconductor layer 101, a light emitting layer 102, and a second type semiconductor layer 103. In some embodiments, the first type semiconductor layer 101, the light emitting layer 102, and the second type semiconductor layer 103 are arranged in the order from the top to the bottom. In some embodiments, the epitaxial structure can be formed on a substrate 00 by any epitaxial growth process known in the art.

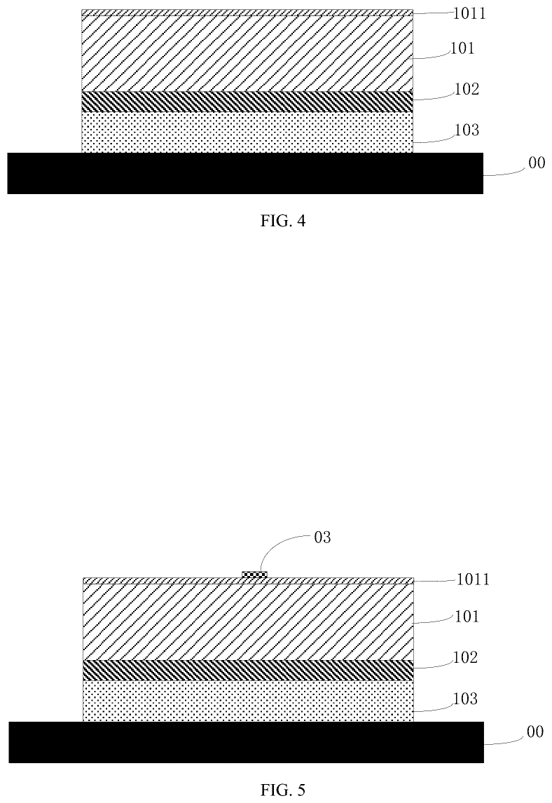

In some embodiments consistent with FIG. 4, a mesa is formed by etching the epitaxial structure (step 2 in FIG. 2). The mesa is formed by etching the first type semiconductor layer 101, the light emitting layer 102, and the second type semiconductor layer 103 sequentially. In some embodiments, sidewalls of the mesa are vertical or inclined with respect to a horizontal plane (e.g., the substrate 00). In some embodiments, the etching process includes a dry etching process. In some embodiments, the etching process includes a plasma etching process.

In some embodiments consistent with FIG. 5, a bottom contact 03 is deposited on the surface of the first type semiconductor layer 101 (step 3 in FIG. 2). The bottom contact 03 is deposited by a chemical vapor process or a physical vapor process known in the art. In some further embodiments, a first patterned mask is provided to cover the whole surface of the mesa with a part of the mesa top exposed during the deposition process. After the deposition, the first patterned mask is removed by a chemical etching method.

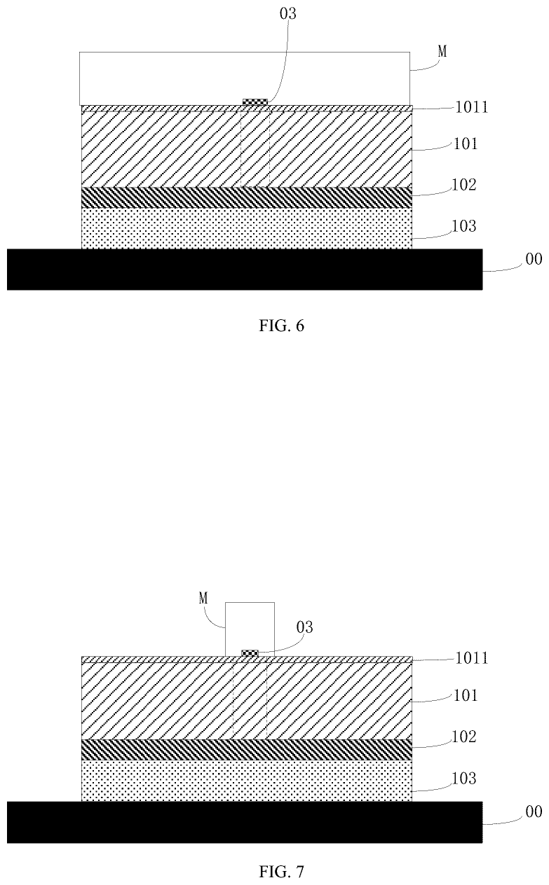

In some embodiments consistent with FIGS. 6, the ion implantation region 103 is formed in the first semiconductor layer 101 (step 4 in FIG. 2). In some embodiments consistent with FIG. 6, the ion implantation region 1013 is formed via an ion implanting process. In some embodiments consistent with FIG. 6, a mask M is formed on the first semiconductor layer 101.

In some embodiments consistent with FIG. 6, a mask M is formed on the first semiconductor layer 101. More particularly, in some embodiments, a preset first semiconductor region and a preset ion implantation region in the first semiconductor layer 101 are defined. In some embodiments, the preset first semiconductor region is under the bottom contact 03 and the preset ion implantation region is around the preset first semiconductor region. More particularly, in some embodiments consistent with FIG. 6, the preset first semiconductor region is the region between the dotted lines and the preset ion implantation region is the regions besides the dotted lines. The preset first semiconductor region is configured to form the first type semiconductor region 1012 and the preset ion implantation region is configured to form the ion implantation region 1013.

In some embodiments consistent with FIG. 7, the mask M is patterned to expose the preset ion implantation region. More particularly, the mask M is patterned by an etching process known in the art. After the etching process, the mask M above the preset second type semiconductor region is maintained and the mask M above the preset ion implantation region is removed to expose the preset ion implantation region.

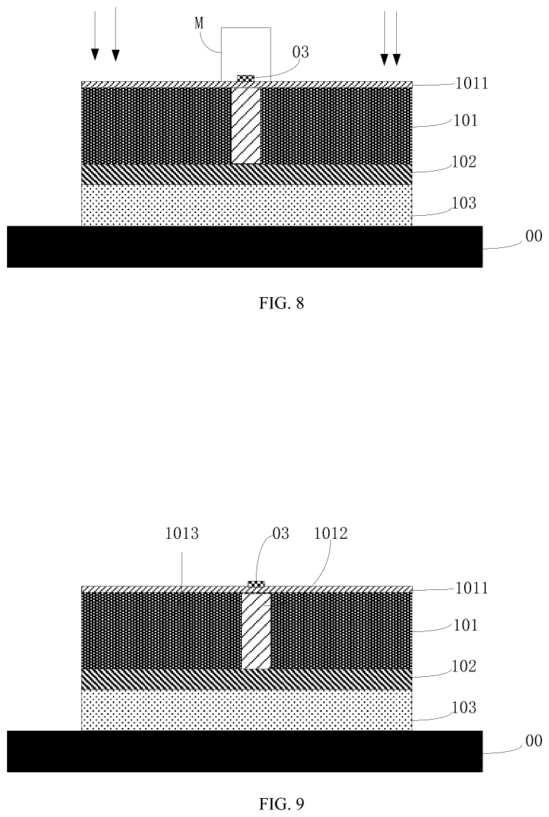

In some embodiments consistent with FIG. 8, the ions are implanted into the preset ion implantation region. More particularly, in some embodiments, the ions are implanted into the second type semiconductor layer 103 to form the ion implantation region 1032. The ion implanting process is performed by an ion implantation technology. In some embodiments consistent with FIG. 8, the implanted ions are selected from one or more of the hydrogen, nitrogen, fluorine, oxygen, carbon, argon, phosphorus, boron, silicon, sulfur, arsenic, chlorine, and metal ions. In some embodiments, the metal ions are selected from one or more of the zinc, copper, indium, aluminum, nickel, titanium, magnesium, chromium, gallium, tin, antimony, tellurium, tungsten, tantalum, germanium, molybdenum, and platinum. More particularly, in some further embodiments, the implantation dose ranges from 10E12 to 10E16. In some embodiments, the ion is implanted into the reflective mirror 1011 corresponding to each ion implanted region 1013.

In some embodiments, the ion implanting process is performed after depositing the bottom contact 03. In some embodiments, the ion implanting process is performed before the etching of the top contact 03 to form the ion implantation region 1013, and then the bottom contact 03 is deposited on the preset first semiconductor region 1012 when another mask covers the ion implantation region 1013.

In some embodiments consistent with FIG. 9, the mask M is removed from the mesa structure. In some embodiments, the mask M is removed by a chemical etching method known in the art.

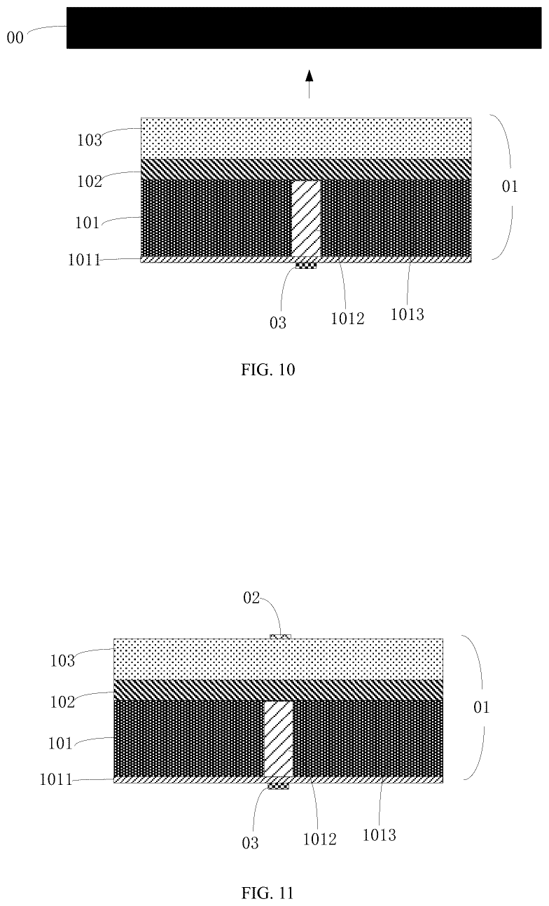

In some embodiments consistent with FIGS. 10 to 11, the top contact 02 is deposited on the second type semiconductor layer 103 (step 5 in FIG. 2). In some embodiments consistent with FIG. 10, before depositing the top contact 02, the mesa is placed upside down to form a mesa structure 01 and the substrate 00 is removed from the mesa structure 01 by a separating process to expose the top of the mesa structure 01. In some embodiments consistent with FIG. 11, the top contact 02 is deposited on the top surface of the second type semiconductor layer 103 in a chemical vapor depositing process or a physical vapor depositing process. In some embodiments consistent with FIG. 11, the area of the top contact 02 is made as small as possible. More particularly, in some further embodiments consistent with FIG. 11, the top contact 02 is a dot.

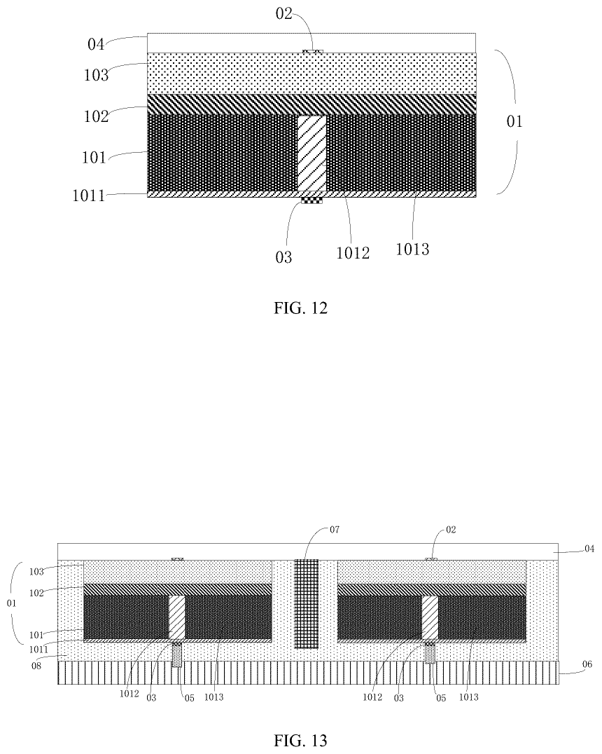

In some embodiment consistent with FIG. 12, the top conductive layer 04 is formed on the mesa structure (step 6 in FIG. 2). More particularly, in some embodiments, the top conductive layer 04 is deposited on the second type semiconductor layer 103 and on the top and sidewalls of the top contact 02, covering the exposed top surface of the second semiconductor layer 103 and the top contact 02. The deposition of the top conductive layer 04 is performed via a chemical vapor deposition method known in the art.

In some embodiments consistent with FIG. 13, a micro display panel is provided. The micro display panel includes a micro LEDs array and an IC back plane 06 formed under the micro LED array. The micro LEDs array includes multiple aforementioned micro LED structures. The micro LED structures are electrically coupled or connected to the IC back plane 06. In some embodiments, the length of the whole micro LEDs array is no more than 5 cm. The length of the back plane is greater than the length of the micro LED array. In some embodiments, the length of the back plane is no greater than 6 cm. The area of the micro LED array is an active display area.

In some embodiments, the micro LED structure further includes a metal bonding structure. More particularly, the metal bonding structure includes a metal bonding layer or a connected hole. For example, as shown in FIG. 13, the metal bonding structure is a connected hole 05 and filled with bonding metal. In some further embodiments, the top surface of the connected hole 05 is coupled with the bottom contact 03, and the bottom surface of the connected hole 05 is coupled with the IC back plane 06. In some embodiments, the center of the metal bonding structure (i.e., the metal bonding layer or the connected hole) and the center of the bottom contact 03 are aligned along a same axis perpendicular to the top surface or bottom surface of the bottom contact 03. In some embodiments, the top conductive layer 04 in the micro display panel is made to cover the whole display panel.

Still referring to FIG. 13, the micro display panel further comprises a dielectric layer 08. The dielectric layer 08 is formed between adjacent mesa structures 01. The material of the dielectric layer 08 is not conductive so that the adjacent micro LEDs are electrically isolated. In some embodiments, the material of the dielectric layer includes at least one of the SiO2, Si3N4, Al2O3, AlN, HfO2, TiO2, and ZrO2.

In some further embodiments, a reflective structure 07 is formed in the dielectric layer 08 between adjacent mesa structures 01 to avoid crosstalk. In some embodiments, the reflective structure 07 does not contact the mesa structures 01. In some embodiment, the top surface of the reflective structure 07 is aligned with the top surface of the mesa structure 01 and the bottom surface of the reflective structure 07 is aligned with the bottom surface of the mesa structure 01. The cross-sectional structure of the reflective structure 07 can be triangle, rectangle, trapezoid, or any other shapes of structures. In some embodiments, the ion implantation region 1013 is formed in the first semiconductor layer 101 and the space between the adjacent mesa structures 01 can be formed as small as possible. In some embodiments, the bottom of the reflective structure 07 extends downward, lower than the bottom of the mesa structure 01.

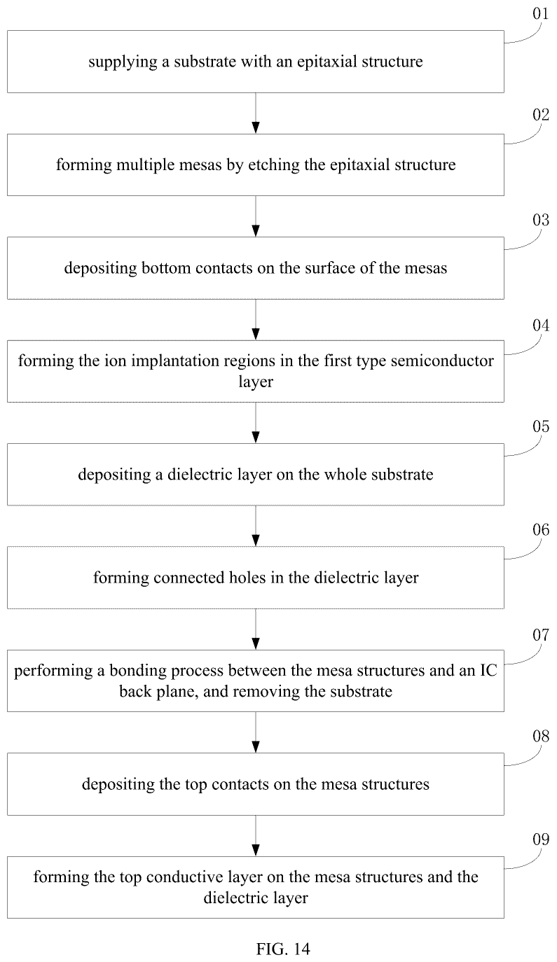

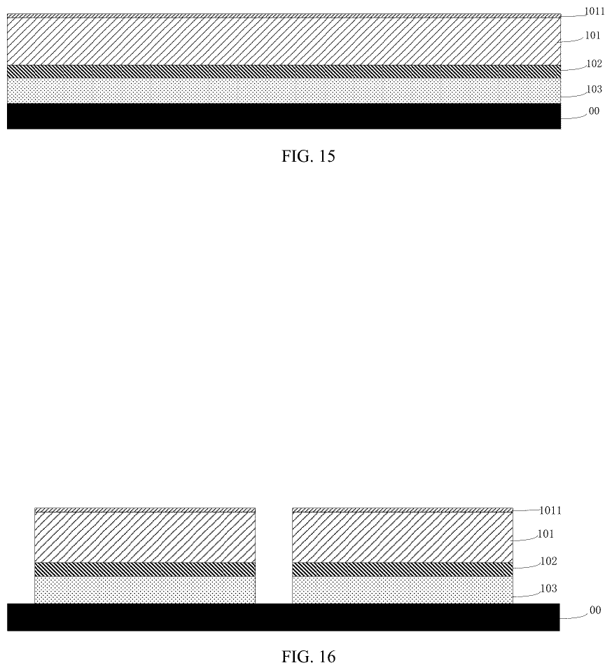

FIG. 14 is a flow chart of a method for manufacturing a micro display panel consistent with the embodiment shown in FIG. 13. FIGS. 15 to 29 are cross-sectional diagrams schematically showing steps for implementing the method of FIG. 14. It is contemplated the disclosed manufacturing method is not limited to the particular micro LED structures shown in FIGS. 15 to 29. In some embodiments consistent with FIGS. 15 to 29, the method of manufacturing the aforementioned micro display panel is described herewith.

In some embodiments consistent with FIG. 15, a substrate 00 with an epitaxial structure is provided (step 1 in FIG. 14). More particularly, the epitaxial structure includes a first type semiconductor layer 101, a light emitting layer 102, and a second type semiconductor layer 103. In some embodiments, the first type semiconductor layer 101, the light emitting layer 102, and the second type semiconductor layer 103 are arranged in the order from up to down. In some embodiments, the epitaxial structure can be formed on a substrate 00 by any epitaxial growth process known in the art. In some further embodiments, the first type semiconductor layer 101 includes one or more reflective mirrors 1011. The reflective mirror 1011 is formed on the surface of the first type semiconductor layer 101.

In some embodiments consistent with FIG. 16, multiple mesas are formed by etching the epitaxial structure (step 2 in FIG. 14). More particularly, the mesas are formed by etching the first type semiconductor layer 101, the light emitting layer 102, and the second type semiconductor layer 103 sequentially. The sidewalls of the mesa are vertical or inclined with respect to a horizontal plane (e.g., the substrate 00). In some embodiments, the etching process is a dry etching process. In some embodiments, the etching process is a plasma etching process.

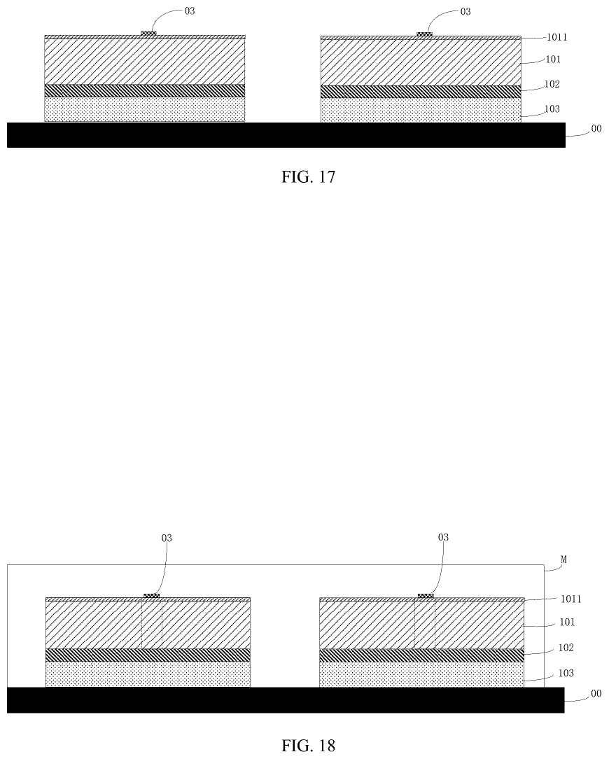

In some embodiments consistent with FIG. 17, the bottom contacts 03 are deposited on the surface of the mesas (step 3 in FIG. 14). More particularly, the bottom contacts 03 are deposited by a chemical vapor process or a conventional physical vapor process. In some further embodiments, a first patterned mask is provided to cover the whole surface of the mesa with a part of the mesa top exposed during the deposition process. In some embodiments, after the deposition process, the first patterned mask is removed by a chemical etching method, forming the bottom contacts on the first semiconductor layer 101.

In some embodiments consistent with FIGS. 18 to 21, the ion implantation regions 1013 are formed in the first type semiconductor layer 101 (step 4 in FIG. 14). The ion implantation regions 1013 are formed via conventional ion plantation process. In some embodiments consistent with FIG. 18, a mask M on the first semiconductor layer 101 is formed, defining preset first semiconductor regions 1012 and preset ion implantation regions 1013 in the first semiconductor layer 101. More particularly, in some embodiments, in each mesa structure 01, the preset second type semiconductor region is under the top contact, as shown in the FIG. 18 as the region between the dotted lines.

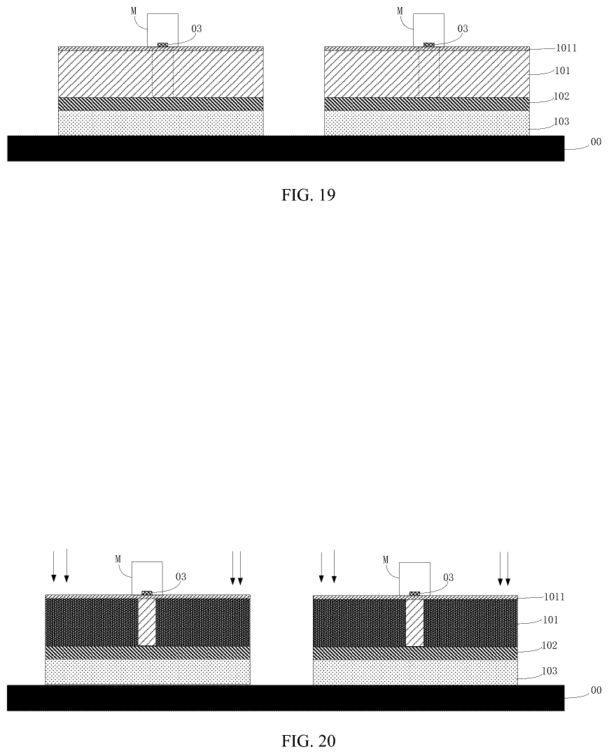

In some embodiments consistent with FIG. 19, the mask M is patterned to expose the preset ion implantation regions. More particularly, in some embodiments, the mask M is patterned by a conventional etching process. In some embodiments, after the etching process, the mask M above the preset second type semiconductor regions are reserved and the mask M above the preset ion implantation regions are removed to expose the preset ion implantation regions.

In some embodiments consistent with FIG. 20, the ions are implanted into the preset ion implantation region. More particularly, in some embodiments, the ions are implanted into the first semiconductor layer to form the ion implantation regions 1013. In some embodiments, the ion implanting process is performed by a conventional ion implantation technology. In some embodiments, the implanted ions comprise at least one of the following ions: hydrogen, nitrogen, fluorine, oxygen, carbon, argon, phosphorus, boron, silicon, sulfur, arsenic, chlorine, and metal ions. In some further embodiments, the metal ions comprise at least one of the zinc, copper, indium, aluminum, nickel, titanium, magnesium, chromium, gallium, tin, antimony, tellurium, tungsten, tantalum, germanium, molybdenum, and platinum. In some embodiments, the implantation dose ranges from 10E12 to 10E16.

In some embodiments, the ion implanting process is performed after depositing the bottom contact 03. In some embodiments, the ion implanting process is performed before the deposition of the bottom contact 03 to form the ion implantation regions 1013, and then the bottom contact 03 is deposited on the preset first semiconductor region when another mask covers the ion implantation regions 1013.

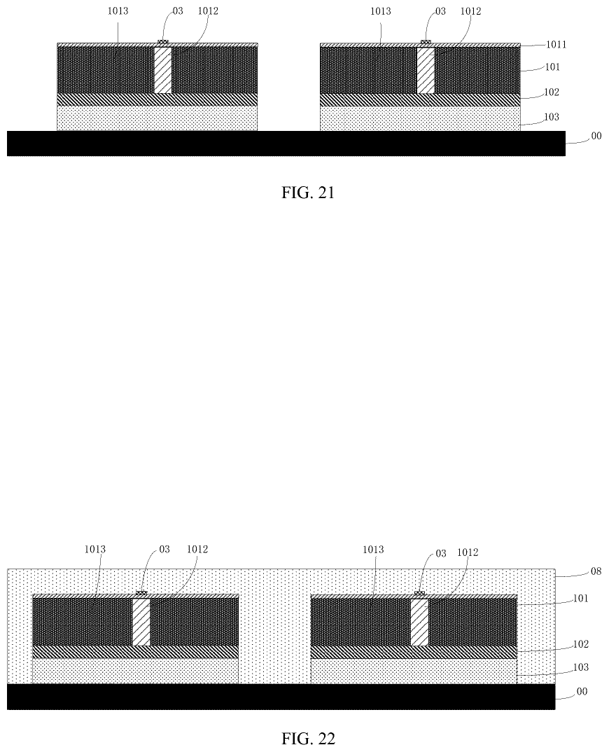

In some embodiments consistent with FIG. 21, the mask M is removed from the mesas. In some embodiments, the mask M is removed by a conventional chemical etching method known in the arts.

In some embodiments consistent with FIG. 22, a dielectric layer 08 is deposited on the substrate 00 (step 5 in FIG. 14). More particularly, the dielectric layer 08 is deposited on the top and the sidewalls of the mesas and on the bottom contacts 03, such that the dielectric layer 08 covers the mesas and the bottom contacts 08.

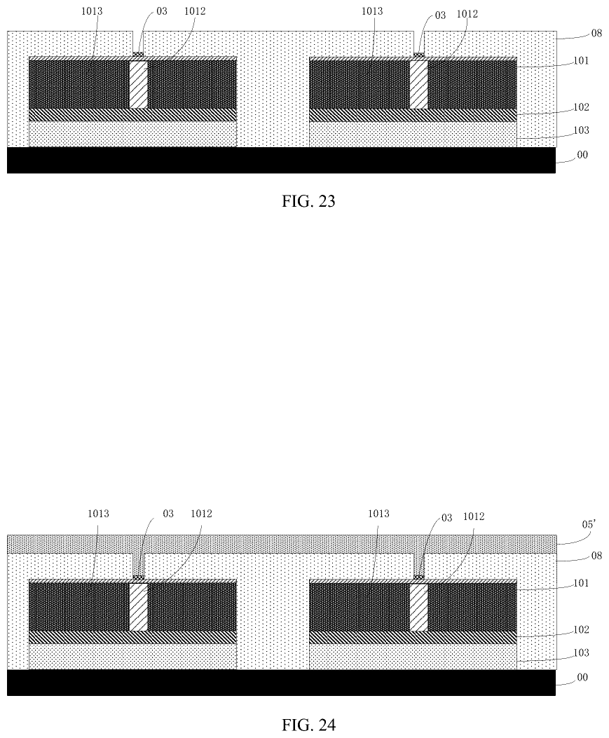

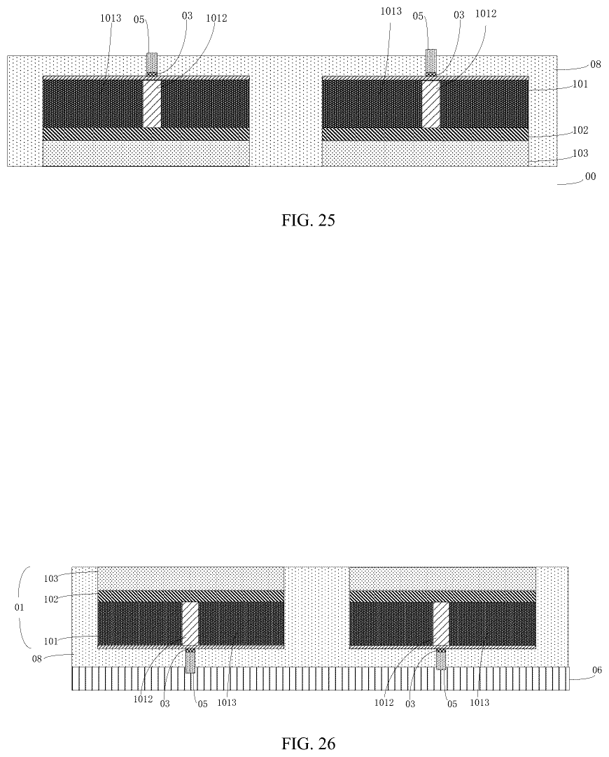

In some embodiments consistent with FIGS. 23 to 25, connected holes are formed in the dielectric layer 08 (step 6 in FIG. 14). In some embodiments, one bottom contact 03 is coupled to one hole. In some embodiments consistent with FIG. 24, the holes are filled with bonding metal to form connected holes 05. More particularly, the bonding metal 05′ is also deposited on the top surface of the dielectric layer 08. In some embodiment consistent with FIG. 25, the top of the bonding metal is polished to expose the top of the dielectric layer 08 and form connected holes 05 by a planarization process. In some embodiments, the planarization process includes a chemical mechanical polishing process. In some embodiments, the top of the bonding metal is above the dielectric layer 08.

In some embodiments consistent with FIG. 26, a bonding process is performed between the mesa structure 01 and an IC back plane 06, removing the substrate 00 (step 7 in FIG. 14). More particularly, the mesas are first positioned upside down to form mesa structures 01. In some embodiments, the connected holes 05 are first aligned with the contact pads on the IC back plane 06. In some further embodiments, the bonding metal in the connected holes 05 are bonded with the contact pads on the surface of the IC back plane 06 via a metal bonding process. In some embodiments, the substrate 00 can be removed either before or after the bonding process, via a substrate separating process known in the art.

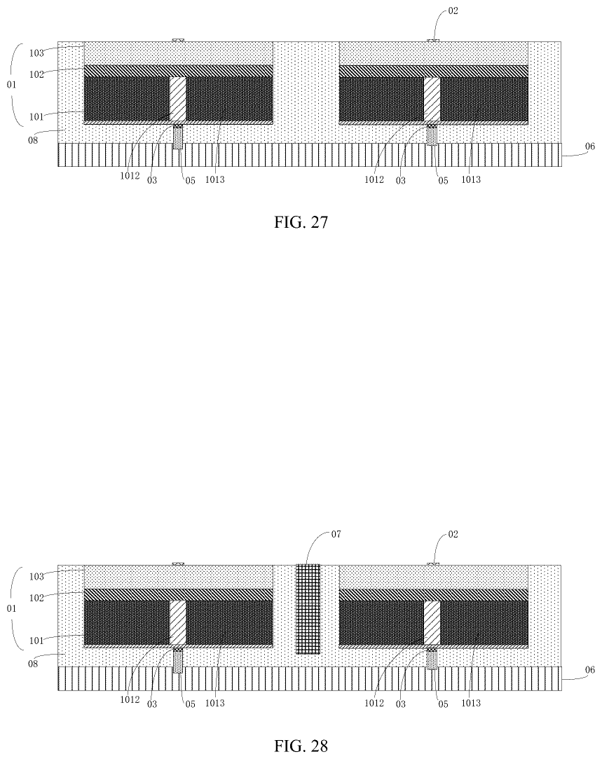

In some embodiments consistent with FIG. 27, the top contacts 02 on the mesa structures 01 are deposited, forming the ion implantation region 1032 (step 8 in FIG. 14). More particularly, in some embodiments consistent with FIG. 27, the bottom of the second semiconductor layer 103 as shown in FIG. 25 is inverted to be the top surface of the second type semiconductor layer 103 by turning the mesas upside down. In some further embodiments, the top contacts 02 are deposited on the top surface of the second type semiconductor layer 103 via a chemical vapor depositing process or a physics vapor depositing process known in the art. In some embodiments, the area of the top contact 02 is configured to be as small as possible. In some embodiments, the area of the top contact 02 is formed as a dot. In some embodiments, a patterned mask is provided to cover the mesa structures 01 with exposing part of the surface of the second semiconductor layer 103. In some embodiments, the patterned mask is a patterned photo-resist. In some further embodiments, the material can be deposited on the surface of the second semiconductor layer 103 to form the top contacts 02.

In some further embodiments consistent with FIG. 28, the reflective structures 07 are formed in the dielectric layer 08 between the adjacent mesas, to decrease the possibility of cross talk. In some embodiments, trenches are formed in the dielectric layer 08 between the adjacent mesas by etching the dielectric layer 08 with a first protective mask. The first protective mask is formed on the mesas and the dielectric layer 08 with the trench regions exposed, protecting the unexpected etching areas. In some embodiments, reflective materials are filled into the trenches to form reflective structures 07 between the adjacent mesas 01. In some embodiments, a second protective mask is formed on the mesas and the dielectric layer 08 with the trenches exposed. In some embodiments, after the aforementioned trenches are etched, the protective masks are etched to a certain thickness and leaves part of protective masks to protect the unexpected filling areas during filling the reflective materials. In some embodiments, the ion implantation region 1013 is formed in the first semiconductor layer 101 and the space between the adjacent mesa structures 01 can be formed as small as possible. In some embodiments, the bottom of the reflective structure 07 extends downward, lower than the bottom of the mesa structure 01. In some embodiments, the ion implantation region 1013 is formed in the second type semiconductor layer 103 and the space between the adjacent mesa structures 01 can be formed as small as possible. In some embodiments, the bottom of the reflective structure 07 extends downward, lower than the bottom of the mesa structure 01.

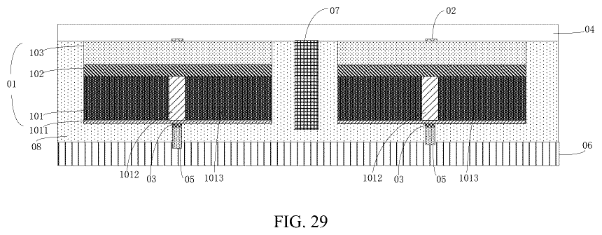

In some embodiments consistent with FIG. 29, the top conductive layer 04 is formed on the mesa structures 01 and the dielectric layer 08 (step 9 in FIG. 14). More particularly, the top conductive layer 08 is deposited on the second type semiconductor layer 103, the top and sidewalls of the top contacts 02 and the dielectric layer 08, covering the exposed top surface of the second semiconductor layer 103, the top contacts 02, and the dielectric layer 08. The deposition of the top conductive layer 04 is performed via a chemical vapor deposition method that is known to a person skilled in the technology field.

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

We claim:

1. A micro light emitting diode (LED) structure, comprising:
a mesa structure, comprising:
a first semiconductor layer having a first conductive type;
a light emitting layer formed on the first semiconductor layer; and
a second semiconductor layer formed on the light emitting layer, the second semiconductor layer having a second conductive type different from the first conductive type;
wherein, the first semiconductor layer comprises:
a semiconductor region; and
an ion implantation region formed around the semiconductor region.

2. The micro LED structure according to claim 1, wherein the first conductive type is P type and the second conductive type is N type.

3. The micro LED structure according to claim 1, further comprising:
a top contact formed on a top surface of the second semiconductor layer, the top contact having the second conductive type; and
a bottom contact formed on a bottom surface of the first semiconductor layer, the bottom contact having the first conductive type and contacting the semiconductor region.

4. The micro LED structure according to claim 3, wherein a center of the bottom contact, a center of the top contact, and a center of the semiconductor region are aligned along a same axis perpendicular to the top surface of the second semiconductor layer, and wherein a diameter of the ion implantation region is greater than or equal to a diameter of the top contact.

5. The micro LED structure according to claim 3, further comprising a top conductive layer, formed on the second semiconductor layer and the top contact.

6. The micro LED structure according to claim 1, wherein
a thickness of the semiconductor region is greater than or equal to a thickness of the ion implantation region,
a diameter of the semiconductor region is greater than or equal to a diameter of the bottom contact, and
a diameter of the ion implantation region is greater than the diameter of the semiconductor region.

7. The micro LED structure according to claim 6, wherein the diameter of the semiconductor region is less than or equal to three times of the diameter of the bottom contact; and the diameter of the ion implantation region is greater than two times of the diameter of the semiconductor region.

8. The micro LED structure according to claim 6, wherein
the thickness of the semiconductor region ranges from 600 nm to 900 nm,
the thickness of the ion implantation region ranges from 500 nm to 800 nm,
the diameter of the ion implantation region ranges from 500 nm to 1250 nm, and
the diameter of the bottom contact ranges from 20 nm to 500 nm.

9. The micro LED structure according to claim 1, wherein the ion implantation region comprises at least one type of implanted ions.

10. The micro LED structure according to claim 9, wherein the implanted ions are selected from one or more of the following ions: hydrogen, nitrogen, fluorine, oxygen, carbon, argon, phosphorus, boron, silicon, sulfur, arsenic, chlorine, and metal ions.

11. The micro LED structure according to claim 10, wherein the metal ions are selected from one or more of zinc, copper, indium, aluminum, nickel, titanium, magnesium, chromium, gallium, tin, antimony, tellurium, tungsten, tantalum, germanium, molybdenum, and platinum.

12. The micro LED structure according to claim 1, wherein a thickness of the first semiconductor layer is greater than a thickness of the second semiconductor layer.

13. The micro LED structure according to claim 12, wherein, the thickness of the first semiconductor layer ranges from 700 nm to 2 μm and the thickness of the second type semiconductor layer ranges from 100 nm to 200 nm.

14. The micro LED structure according to claim 1, wherein a thickness of the light emitting layer is less than a thickness of the first semiconductor layer.

15. The micro LED structure according to claim 1, wherein the light emitting layer is formed by a quantum well layer located between the first semiconductor layer and the second semiconductor layer.

16. The micro LED structure according to claim 15, wherein a thickness of the quantum well layer is less than or equal to 30 nm.

17. The micro LED structure according to claim 15, wherein the quantum well layer comprises three or less than three pairs of quantum wells.

18. The micro LED structure according to claim 1, further comprising a first reflective mirror formed on the bottom surface of the first semiconductor layer.

19. The micro LED structure according to claim 18, further comprising a second reflective mirror formed inside of the first semiconductor layer.

20. The micro LED structure according to claim 1, wherein the ion implantation region having a resistance higher than a resistance of the semiconductor region.

21. A micro display panel, comprising:
a micro light emitting diode (LED) array, comprising:
a first micro LED structure according to claim 1, the first micro LED structure comprising a first mesa structure; and
an integrated circuit (IC) back plane formed under the first micro LED structure,
wherein the first micro LED structure is electrically coupled to IC back plane.

22. The micro display panel according to claim 21, wherein the micro LED structure further comprising:
a bottom contact formed on a bottom surface of the first mesa structure, and
a bottom metal bonding structure coupled with a bottom surface of the bottom contact, wherein a center of the bottom metal bonding structure and a center of the bottom contact are aligned along a same axis perpendicular to the bottom surface of the bottom contact

23. The micro display panel according to claim 18, wherein:
the bottom metal bonding structure comprises a connected hole, and
the micro display panel further comprises a top conductive layer formed on the first mesa structure,
wherein a first side of the connected hole is connected to the bottom contact, and a second side of the connected hole is connected to the IC back plane.

24. The micro display panel according to claim 21, further comprising:
a second micro LED structure according to claim 1, the second micro LED structure comprising a second mesa structure; and
a dielectric layer,
wherein the second mesa structure is located adjacent to the first mesa structure, and
wherein the dielectric layer is not conductive and is formed between the first and second mesa structures.

25. The micro display panel according to claim 24, wherein material of the dielectric layer is at least one of SiO₂, Si₃N₄, Al₂O₃, AlN, HfO₂, TiO₂ and ZrO₂.

26. The micro display panel according to claim 24, further comprising a reflective structure formed in the dielectric layer and between the first and second mesa structures, wherein the reflective structure does not contact the mesa structures.

27. The micro display panel according to claim 26, wherein the reflective structure has:
a top surface aligned with top surfaces of the first and second mesa structures; and
a bottom surface aligned with bottom surfaces of the first and second mesa structures.
